(19) United States
(12) Patent Application Publication
(10) Pub. No.: US 2023/0200126 A1
(43) Pub. Date: Jun. 22, 2023

(54) DISPLAY APPARATUS

(71) Applicant: LG Display Co., Ltd., Seoul (KR)

(72) Inventors: JU-HEON HYEON, Paju-si (KR); MI-KYUNG LEE, Paju-si (KR); MIN GOOK, Paju-si (KR)

(73) Assignee: LG Display Co., Ltd., Seoul (KR)

(21) Appl. No.: 18/072,333

(22) Filed: Nov. 30, 2022

(30) Foreign Application Priority Data
Dec. 22, 2021 (KR) 10-2021-0184919

(51) Int. Cl. H01L 31/036

(52) U.S. Cl. CPC H01L 51/5284; H01L 27/3244; H01L 51/524; H01L 51/5256; H01L 27/323

(57) ABSTRACT

A display apparatus can include a display panel for displaying an image, a front member disposed on the display panel, and a light absorption layer disposed inside the front member. As a result, while improving the visibility of the display apparatus, the thickness of the display apparatus can be minimized and the manufacturing cost of the display apparatus can be reduced.

### CROSS-REFERENCE TO RELATED APPLICATIONS

The present application claims the priority benefit of Korean Patent Application No. 10-2021-0184919 filed in Republic of Korea on Dec. 22, 2021, the entire contents of which are hereby expressly incorporated by reference into the present application.

### BACKGROUND

### Field of the Invention

The present disclosure relates to a display apparatus, and more particularly, to a display apparatus capable of improving a visibility by reducing the reflection of an external light.

### Discussion of the Related Art

Recently, with a development of multimedia, an importance of a flat display apparatus has been increased. In response to this, flat display apparatuses such as a liquid crystal display apparatus and an organic electroluminescent display apparatus have been commercialized. Among these flat display apparatuses, the organic electroluminescent display apparatus is currently widely used and offers advantages such as high response speed, high luminance and good viewing angle.

In the organic electroluminescent display apparatus, a polarizing plate is attached to a front surface of a display panel in order to prevent deterioration of visibility due to the reflection of an external light. However, the polarizing plate can have a limitation in that the overall luminance of the organic electroluminescent display apparatus can be reduced and the thickness of the organic electroluminescent display apparatus can increases.

Furthermore, although a foldable display apparatus has been recently explored, the polarizing plate can cause a limitation in folding the organic electroluminescent display apparatus.

### SUMMARY OF THE DISCLOSURE

Accordingly, the present disclosure is directed to a display apparatus that substantially obviates or addresses one or more of the limitations and disadvantages associated with the related art.

An advantage of the present disclosure is to provide a display apparatus which can absorb an external light input from an outside by forming a light absorption layer inside a front member and thus reduce a light reflection.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display apparatus includes a display panel for displaying an image, a front member disposed on the display panel, and a light absorption layer disposed inside the front member.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view illustrating a first example of a display apparatus according to an embodiment of the present disclosure;

FIG. 2 is a circuit diagram of a sub-pixel SP of an organic light emitting display panel provided in a display apparatus according to an embodiment of the present disclosure;

FIG. 3 is a view illustrating a second example of a display apparatus according to an embodiment of the present disclosure;

FIG. 4 is a cross-sectional view illustrating a structure of a display panel according to an embodiment of the present disclosure;

FIG. 5 is a view illustrating a third example of a display apparatus according to an embodiment of the present disclosure;

FIG. 6 is a view illustrating a fourth example of a display apparatus according to an embodiment of the present disclosure;

FIG. 7 is a view illustrating a fifth example of a display apparatus according to an embodiment of the present disclosure;

FIG. 8 is a view illustrating a sixth example of a display apparatus according to an embodiment of the present disclosure; and

FIG. 9 is a view illustrating a seventh example of a display apparatus according to an embodiment of the present disclosure.

### DETAILED DESCRIPTION OF THE EMBODIMENTS

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present invention, and the present invention is only defined by the scope of the claims.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When ‘comprising’, ‘including’, ‘having’, ‘consisting’, and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

Respective features of various embodiments of the present disclosure can be partially or wholly connected to or combined with each other and can be technically interlocked and driven variously, and respective embodiments can be independently implemented from each other or can be implemented together with a related relationship.

In describing components of the present disclosure, terms such as first, second, A, B, (a), (b) and the like can be used. These terms are only for distinguishing the components from other components, and an essence, order, order, or number of the components is not limited by the terms. Further, when it is described that a component is “connected”, “coupled” or “contact” to another component, the component can be directly connected or contact the another component, but it should be understood that other component can be “interposed” between the components or the components can be “connected,” “coupled,” or “contact” through one or more other components.

In this disclosure, a “display apparatus” can include a display apparatus in a narrow sense, such as a display module including a display panel and a driving portion for driving the display panel, or can include a display module, and/or an application product including the display module or a set device that is an end-user device. Furthermore, the “display apparatus” can include a complete product or final product which is a notebook computer, a television, a computer monitor, an automotive device or equipment display including other type of vehicle, or a set electronic device or set device or set apparatus such as a mobile electronic device which is a smart phone, an electronic pad or the like. The “display apparatus” can be any module, unit, device, apparatus, component, etc. or a part thereof, that can provide a displaying operation.

Further, all the components of each display apparatus according to all embodiments of the present disclosure are operatively coupled and configured. In this regard, each display apparatus of the present disclosure includes components/layers needed to provide a display function as well understood to one skilled in the art. For instance, a display panel of each display apparatus of the present disclosure can include various elements such as pixel/sub-pixel configurations and one or more components for driving the pixel/subpixel configurations. Further, each display panel can also provide a touch function in addition to the display function. In addition, various examples of an adhesive (e.g., ADH, ADH_1, ADH_2, etc.) can be an adhesive material or layer or film.

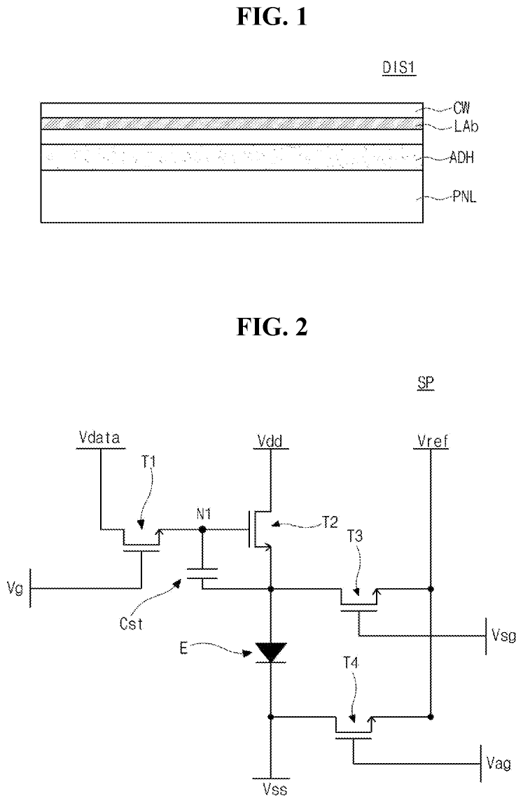

FIG. 1 is a view illustrating a first example of a display apparatus according to an embodiment of the present disclosure. For example, the display apparatus according to the present disclosure relates to a foldable display apparatus that can be folded and unfolded, but is not limited thereto.

As shown in FIG. 1, a display apparatus DIS1 can include a display panel PNL on which an actual image is displayed, a front member CW disposed on the display panel PNL, and an adhesive ADH which is disposed between the display panel PNL and the front member CW and attaches the front member CW to the display panel PNL. The front member CW can be referred to herein as a protective module/member/unit configured to protect the display panel PNL.

As the display panel PNL, various display panels such as an organic electroluminescent display panel, a liquid crystal display panel, an electrophoretic display panel, a mini LED (Light Emitting Diode) display panel, and a micro LED display panel can be used. Hereinafter, for convenience of explanations, an organic electroluminescent display panel is described as an example.

Although described later, the display panel PNL can be a COE (Color filter On Encapsulation) structure in which a color filter layer is disposed on an encapsulation layer, but is not limited thereto.

In the display panel PNL of the COE structure, the color filter layer absorbs most of a light input from the outside and transmits only a light of a corresponding wavelength among the light input from the outside to an inside of the display panel PNL. Also the color filter layer absorbs some of a light reflected inside the display panel PNL and transmits only a portion of the reflected light, thereby minimizing a reflection of the external light.

For example, in the display apparatus DIS1 according to the present disclosure, by including the color filter layer on the encapsulation layer of the display panel PNL, a reflection of the external light can be minimized, so that the display apparatus DIS1 does not include a separate polarizing plate and can improve a visibility.

Therefore, in the display apparatus DIS1 according to the present disclosure, since the front member CW is directly attached to a top (or front or upper surface) of the display panel PNL without a polarizing plate, a manufacturing cost can be reduced and a thickness of the display apparatus DIS1 can be reduced.

The front member CW is disposed on the display panel PNL to protect the display panel PNL from an external impact and/or foreign substances such as or moisture. The front member CW can be formed in a multi-layered structure. For example, the front member CW can include a foldable cover glass or a flexible film, as well as various films or layers for protecting the front glass or film. The front member CW can be formed at a thickness of 100 μm or less for folding, but is not limited thereto.

The adhesive ADH may be an OCA (Optical Clear Adhesive), and can be configured in form of a film. For example, the adhesive ADH is disposed between the display panel PNL and the front member CW, and attaches the front member CW to the display panel PNL or attaches the display panel PNL to the front member CW by to applying pressure to the display panel PNL and the front member CW.

A light absorption layer LAB can be formed in the front member CW, e.g., the light absorption layer LAB can be included within the front member CW. The light absorption layer LAB can absorb an external light incident on the display apparatus DIS1 from the outside and prevent a light from being reflected on a display surface of the display apparatus DIS, thereby further improving a visibility of the display apparatus DIS.

Alternatively, the light absorption layer LAB can be formed below the front member CW instead of inside the front member CW.

In one example, the adhesive ADH can be formed as a black adhesive to absorb an external light incident from the outside, thereby preventing a light reflection. When a black adhesive ADH, however, the following issues can arise.

The black adhesive (ADH) can be made of an organic material such as an acrylic, urethane, or silicone-based material, and can be manufactured by adding black dyes or pigments in an OCA. However, since the OCA is configured in a form of a film, it is formed in a semi-dry state having a certain viscosity, not in a liquid state. Accordingly, when the black dyes or pigments are mixed with the organic material, the dyes or pigments may not be uniformly mixed with the organic material. Such non-uniform mixing may not completely prevent a reflection of an external light, but may cause limitations such as bright spots on a screen due to a difference in reflectance according to areas.

On the other hand, in other examples of the present disclosure, since dyes or pigments are included in a liquid material, a uniform mixing of the dye or pigments can be possible. Accordingly, since uniform absorption of a light incident from the outside is possible, issues such as bright spots on a screen due to a difference in reflectance can be prevented effectively.

Hereinafter, specific embodiments of the present disclosure are described. Hereinafter, an organic electroluminescent display apparatus is described for convenience of explanations. However, the present disclosure is not only applied to the organic electroluminescent display apparatus, but can be applied to various types of display apparatuses.

FIG. 2 is a circuit diagram of a sub-pixel SP of an organic light emitting display panel provided in a display apparatus according to an embodiment of the present disclosure.

The organic electroluminescent display panel PNL according to the embodiment of the present disclosure can include a display area and a pad area, and the display area can include a plurality of sub-pixels SP. Each sub-pixel SP can display a single color in the organic electroluminescent display apparatus. For example, each sub-pixel SP displays any one of red, green, blue, and white. In this case, the red, green, blue, and white sub-pixels SP can constitute one pixel. In other variations, other combinations of color sub-pixels SP can be used to form each pixel. The plurality of sub-pixels SP can be arranged on a substrate of the organic electroluminescent display apparatus, and a plurality of lines can be disposed between the plurality of sub-pixels SP in the display area.

In addition, various lines electrically connected to the lines disposed in the display area and applying signals to light emitting elements of the organic electroluminescent display apparatus can be disposed in the pad area as well. The lines can include, for example, a Vdd line, a Vdata line, a reference line (e.g., Vref line), and a Vss line, but are not limited thereto.

As shown in FIG. 2, each sub-pixel SP of the organic electroluminescent display panel PNL according to the present disclosure can include a switching thin film transistor (TFT) T1, a driving thin film transistor T2, a storage capacitor Cst, a sensing thin film transistor T3, an auxiliary thin film transistor T4, and a light emitting element E.

Since the sub-pixel SP of the organic electroluminescent display apparatus according to this example of the present disclosure includes four thin film transistors and one capacitor, it can be referred to as a 4T1C structure. The structure of the sub-pixel SP of the organic electroluminescent display apparatus according to the present disclosure is not limited thereto. For example, the sub-pixel SP of the organic electroluminescent display apparatus can have one of various structures such as a 4T2C structure including four thin film transistors and two capacitors, a 5T2C structure including five thin film transistors and two capacitors, a 6T2C structure including six thin film transistors and two capacitors, and a 7T2C structure including seven thin film transistors and two capacitors.

Referring to FIG. 2, each of the four thin film transistors included in the sub-pixel SP can include a semiconductor layer, a gate electrode, a source electrode, and a drain electrode, and can be a P-type thin film transistor or an N-type thin film transistor. FIG. 2 shows an N-type thin film transistor by way of example, but the present disclosure is not limited thereto.

The switching thin film transistor T1 can include a drain electrode connected to a data line (e.g., Vdata line), a source electrode connected to a first node N1, and a gate electrode connected to a gate line (e.g., Vg line) among a plurality of gate lines disposed in the organic electroluminescent display apparatus. The switching thin film transistor T1 can be turned on based on a gate voltage Vg applied from a gate driving portion to a gate line, and can charge the first node N1 with a data voltage Vdata applied from a data driving portion to a data line among a plurality of data lines disposed in the organic electroluminescent display apparatus.

The drive thin film transistor T2 can include a drain electrode connected to a high potential line (e.g., a Vdd line), a source electrode connected to an anode of the light emitting element E, and a gate electrode connected to the first node N1. The driving thin film transistor T2 can be turned on when a voltage of the first node N1 is higher than a threshold voltage (Vth), and the driving thin film transistor T2 can be turned off when a voltage of the first node N1 is lower than the threshold voltage. The driving thin film transistor T2 can deliver a driving current received from the Vdd line to the light emitting element E. The light emitting element E can be an organic light emitting diode, but is not limited thereto.

The storage capacitor CST can include an electrode connected to the first node N1 and an electrode connected to the source electrode of the driving thin film transistor T2. The storage capacitor Cst maintains a potential difference between the gate electrode and the source electrode of the driving thin film transistor T2 during an emission time when the light emitting element E emits a light, thereby providing a constant driving current to the light emitting element E.

The sensing thin film transistor T3 can include a drain electrode connected to the source electrode of the drive thin film transistor T2, a source electrode connected to the reference line and a gate electrode connected to a sensing gate line (e.g., a Vsg line). The sensing thin film transistor T3 can be a thin film transistor for sensing the threshold voltage of the driving thin film transistor T2.

The auxiliary thin film transistor T4 can include a drain electrode electrically connected to a cathode of the light emitting element E, a source electrode electrically connected to a reference line, and a gate electrode electrically connected to an auxiliary gate line (e.g., a Vag line). The auxiliary thin film transistor T4 can be turned on in the emission time and provide a low potential voltage (e.g., a Vss voltage) to the cathode of the light emitting element E.

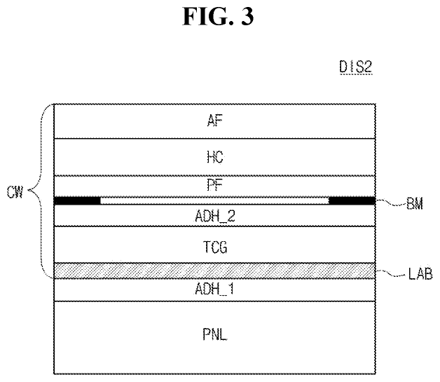

FIG. 3 is a view illustrating a second example of a display apparatus according to an embodiment of the present disclosure.

As shown in FIG. 3, a display apparatus DIS2 according to the embodiment of the present disclosure can include a display panel PNL on which an actual image is displayed, a front member CW disposed on the display panel PNL to protect the display panel PNL, and a first adhesive ADH_1 for attaching the front member CW to the display panel PNL.

The front member CW can include a front glass TCG disposed on the display panel PNL, a protective film PF disposed on the front glass TCG, and a coating layer HC disposed on the protective film PF, and a functional layer AF.

The front glass TCG can be attached to the display panel PNL by the first adhesive ADH_1, and the protective film PF can be attached to the front glass TCG by a second adhesive ADH_2. In addition, a light absorption layer LAB can be directly coated to a bottom surface (or lower surface) of the front glass TCG, and the coating layer HC can be directly laminated on the protective film PF, and the functional layer AF can be also directly laminated on the coating layer HC.

The display panel PNL can be a liquid crystal display panel, an organic electroluminescent display panel, an electrophoretic display panel, a mini LED display panel, or a micro LED display panel, but the organic electroluminescent display panel is mainly described below.

Additional features of the display apparatus DIS2 will be discussed later hereinbelow.

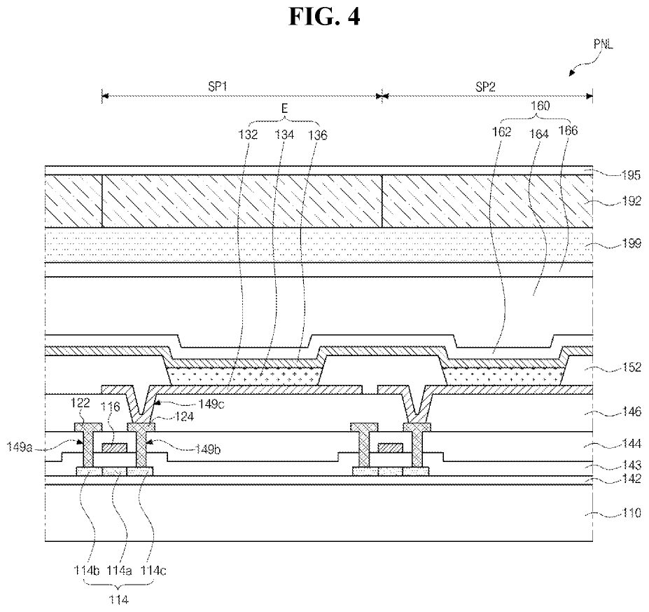

FIG. 4 is a cross-sectional view illustrating a structure of a display panel according to an embodiment of the present disclosure. In FIG. 4, two adjacent sub-pixels SP1 and SP2 are shown for convenience of explanations. The display panel PNL shown in FIG. 4 can be used as the display panel PNL in FIGS. 1, 3 and 5-9. Further, the sub-pixel SP configuration of FIG. 2 can be used in any display panel discussed in the present disclosure.

In addition, any feature or element described in connection with any one example of a display apparatus of the present disclosure can be equally used and applied to any other example of the display apparatus of the present disclosure.

As shown in FIG. 4, the display panel PNL according to the present disclosure can include a plurality of sub-pixels SP1 and SP2 disposed on a substrate 110. The sub-pixels SP1 and SP2 can be color sub-pixels among R, G, and B sub-pixels that display red, blue, and green colors.

A thin film transistor T can be disposed in each of the sub-pixels SP1 and SP2. Various thin film transistors such as a switching thin film transistor, a driving thin film transistor, a sensing thin film transistor, and an auxiliary thin film transistor can be arranged in each of the sub-pixels SP1 and SP2, but only one thin film transistor T is shown in the drawing for convenience of explanations. Accordingly, the thin film transistor T can be the switching thin film transistor, the driving thin film transistor, the sensing thin film transistor, or the auxiliary thin film transistor.

Since the switching thin film transistor, the driving thin film transistor, the sensing thin film transistor, and the auxiliary thin film transistor can all have the same structure, the structure of all the thin film transistors can be expressed with one thin film transistor T.

The thin film transistor T can include a semiconductor layer 114 formed on a buffer layer 142 formed on the substrate 110, a gate insulating layer 143 disposed on the buffer layer 142 to cover the semiconductor layer 114, a gate electrode 116 disposed on the gate insulating layer 143, an inter-layered insulating layer 144 disposed on the gate insulating layer 143 to cover the gate electrode 116, and a source electrode 122 and a drain electrode 124 disposed on the inter-layered insulating layer 144.

The substrate 110 can be made of a foldable plastic material. For example, the substrate 110 can include polyimide (PI), polyethylene terephthalate (PET), polyethylene naphthalate (PEN), polycarbonate (PC), polyethersulfone (PES), polyarylate (PAR), polysulfone (PSF), or cyclic-olefin copolymer (COC). The substrate 110 of the present disclosure is not limited to such the flexible material, but can be formed of a foldable thin glass.

The buffer layer 142 can protect the thin film transistor T formed in a subsequent process from impurities such as alkali ions leaking from the substrate 110 or block moisture that can penetrate from an outside. The buffer layer 142 can be configured with a single layer made of silicon oxide (SiOx) or silicon nitride (SiNx) or a multi layers thereof.

The semiconductor layer 114 can be formed of an amorphous semiconductor such as amorphous silicon (a-Si), a crystalline semiconductor such as polycrystalline silicon (p-Si), or an oxide semiconductor such as indium gallium zinc oxide (IGZO), but is not limited thereto. The semiconductor layer 114 can include a channel region 114a at a central region, and a source region 114b and a drain region 114c which are doped regions on both sides of the channel region 114a. Here the source region 114b can be a drain region, and the drain region 114c can be a source region, depending on the source and drain electrodes of the thin film transistor T.

The gate electrode 116 can be formed of a single layer or a plurality of layers made of a metal(s) such as Cr, Mo, Ta, Cu, Ti, Al, and/or an Al alloy, but is not limited thereto.

The inter-layered insulating layer 144 can configured with a single layer or a plurality of layers made of an organic material such as photoacrylic or made of an inorganic material such as SiNx or SiOx. Alternatively, the inter-layered insulating layer 144 can be configured with a plurality of layers of an organic material layer and an inorganic material layer.

The source electrode 122 and the drain electrode 124 can be formed of a single layer or a plurality of layers made of a metal(s) such as Cr, Mo, Ta, Cu, Ti, Al, and/or an Al alloy, but is limited thereto.

The source electrode 122 and the drain electrode 124 can be in ohmic contact with the source region 114b and the drain region 114c of the semiconductor layer 114 through a first contact hole 149a and a second contact hole 149b formed in the gate insulating layer 143 and the inter-layered insulating layer 144, respectively.

A bottom shield metal layer can be disposed on the substrate 110 and below the semiconductor layer 114. The bottom shield metal layer can serve to minimize a back channel phenomenon caused by charges trapped at the substrate 110 to prevent an after-image or a deterioration of transistor performance. The bottom shield metal layer can be configured with a single layer or a plurality of layers using Ti, Mo and/or an alloy of Ti and Mo, but is not limited thereto.

A passivation layer 146 can be formed on the substrate 110 having the thin film transistor T thereon. The passivation layer 146 can be formed of an organic material such as photoacrylic, but is not limited thereto. For example, the passivation layer 146 can be configured with a plurality of layers including an inorganic layer and an organic layer. A third contact hole 149c can be formed in the passivation layer 146.

An anode 132 electrically connected to the drain electrode 124 of the thin film transistor T through the third contact hole 149c can be formed in each of the sub-pixels SP1 and SP2 on the passivation layer 146. The anode 132 can be made of a single layer or a plurality of layers using a metal(s) such as Ca, Ba, Mg, Al, and Ag and/or an alloy thereof. The anode 132 is not limited to the above materials.

A bank layer 152 can be formed at a boundary of each sub-pixel SP on the passivation layer 146. The bank layer 152 can be a separation wall defining the sub-pixel SP. For example, the bank layer 152 can partition the sub-pixels SP to prevent a light of a specific color output from an adjacent sub-pixel from being mixed and output.

A light emitting layer 134 can be formed on the anode 132 and on a portion of an inclined surface of the bank layer 152. The light emitting layer 134 can be an R-emitting layer which is formed in an R sub-pixel and emits a red light, a G-emitting layer which is formed in a G sub-pixel and emits a green light, or a B-emitting layer which is formed in a B sub-pixel and emits a blue light. Alternatively, the light emitting layer 134 can be a W-emitting layer that emits a white light. The light emitting layer 134 can be, but not limited to, an organic light emitting layer. For example, the light-emitting layer 134 can be an inorganic light emitting layer, a quantum dot light emitting layer, or a micro LED.

In the light emitting layer 134, not only an emission layer, but also an electron injection layer and a hole injection layer for respectively injecting electrons and holes into the emission layer, and an electron transport layer and a hole transport layer for respectively transporting the injected electrons and holes to the emission layer can be formed.

A cathode 136 can be formed over the entire display apparatus on the light emitting layer 134. The cathode 136 can be made of a transparent conductive material such as indium tin oxide (ITO) or indium zinc oxide (IZO), or a thin metal through which a visible light is transmitted, but is not limited thereto.

The anode 132, the light emitting layer 134, and the cathode 136 can form the light emitting element E and output a light having a specific wavelength as a signal is applied.

An encapsulation layer 160 can be formed on the cathode 136. The encapsulation layer 160 can include a first encapsulation layer 162 made of an inorganic material, a second encapsulation layer 164 made of an organic material, and a third encapsulation layer 166 made of an inorganic material. The inorganic material can include, but is not limited to, SiNx or SiOx. In addition, the organic material can include, but is not limited to, polyethylene terephthalate, polyethylene naphthalate, polycarbonate, polyimide, polyethylene sulfonate, polyoxymethylene, polyarylate, or a mixture thereof.

A color filter layer 192 can be formed on the third encapsulation layer 166. The color filter layer 192 can include R, G, and B color filters formed in the respective sub-pixels SP1 and SP2.

The color filter layer 192 can implement R, G, and B colors by transmitting only a light of a corresponding wavelength among a light emitted from the light emitting element E and absorbing a light of other wavelengths. When the light emitting layer 134 of the light emitting element E emits a white light, R, G, and B colors are implemented by the color filter layer 192.

In addition, when the light emitting layer 134 of the light emitting element E emits a monochromatic light, for example, a light of an R, G, or B color, the R, G, and B color filters are formed in the corresponding sub-pixels SP1 and SP2, respectively. For example, the R color filter is disposed on the sub-pixel emitting a red light, the G color filter is disposed on the sub-pixel emitting a green light, and the B color filter is disposed on the sub-pixel emitting a blue light. The color filter layer 192 filters a light of the corresponding color and outputs an input light as a light having a higher purity color.

As described above, as the color filter layer 192 is disposed on the encapsulation layer 160, a portion of an external light input from the outside and incident into the inside of the display panel PNL is absorbed, and a portion of the external light that is reflected in the inside and is again output to the outside is absorbed. Accordingly, a reflectance for the external light can be significantly reduced, and thus a visibility can be improved due to the decrease in reflectance without using a separate polarizing plate in the display apparatus.

According to the present disclosure, as the color filter layer 192 is formed on the encapsulation layer 160, the reflectance for the external light can be reduced to about 30% or less even when a polarizing plate is not provided.

Meanwhile, a planarization layer 195 can be formed on the color filter layer 192. The planarization layer 195 can be made of an organic material such as photoacrylic, but is not limited thereto.

A touch sensor 199 can be disposed inside the display panel PNL, for example, on the encapsulation layer 160 or on the planarization layer 195. In this embodiment, the touch sensor 199 being disposed on the encapsulation layer 160 is shown by way of example. In this case, the touch sensor 199 (e.g., touch sensor layer) can be disposed between the third encapsulation layer 166 and the color filter layer 192 below the planarization layer 195.

Now, referring back to FIG. 3, the front glass TCG can be disposed on the display panel PNL, and the protective film PF can be disposed on the front glass TCG. The front glass TCG can transmit an image of the display panel PNL to the outside as it is, and can protect the display panel PNL from an external impact and an external environment or stress. The protective film PF can be attached to the front glass TCG by the second adhesive ADH_2. Since the front glass TCG is formed at a thin thickness of several tens of micrometers, the front glass TCG can be damaged by a small external impact or continuous folding. The protective film PF can protect the front glass TCG from compressive and elongational stress which can be caused by an external impact or continuous folding. In addition, the protective film PF can prevent a glass powder from scattering to the outside when the front glass TCG is damaged by an external impact or stress to generate the glass powder.

As the protective film PF, a transparent film such as polyethylene terephthalate can be mainly used, but is not limited thereto. For example, the protective film PF can use triacetyl cellulose, cycloolefin polymer (COP), or a combination thereof.

A black matrix BM can be formed on an edge of the lower surface of the protective film PF to prevent a light output from the display panel PNL from leaking to the edge of the display apparatus DIS2. The black matrix BM can be formed of a metal oxide such as CrOx, a black resin, or black ink, but is not limited thereto.

The coating layer HC can be laminated on the protective film PF to protect the display apparatus DIS2 from scratches. The coating layer HC can be formed by laminating an organic material such as a urethane acrylic resin, a methacrylic resin, or a silsesquioxane compound, but is not limited thereto.

The functional layer AF can be formed by being laminated on the coating layer HC or can be formed by surface-treating a top surface (or upper surface) of the coating layer HC. The functional layer AF can include, but is not limited to, an anti-finger print layer, an anti-contamination layer, and an anti-glare layer.

The anti-fingerprint layer can be formed by using a method that increases a wettability of the coat layer HC so that the wettability is spread out and is not noticeable even when a fingerprint component is attached.

The anti-contamination layer can be formed by laminating a material having a good water repellency, such as a hydrocarbon-based compound, a silicone-based compound, a chlorine compound, and a fluorine-based compound.

The anti-glare layer can be formed by coating SiOx on the coating layer HC by a spray method or by single or double surface treatment of the coating layer HC, to generate a scattering effect.

The first adhesive ADH_1 for bonding the display panel PNL and the front glass TCG and the second adhesive ADH_2 for bonding the front glass TCG and the protective film PF can be formed of a tape-type adhesive (e.g., OCA) using an acrylic adhesive material, which has a good transparency and is widely used, but is not limited thereto. For example, as the second adhesive ADH_2, various adhesive materials such as silicone and urethane can be used.

In the display apparatus DIS2 according to the embodiment of the present disclosure, the light absorption layer LAB can be formed on the bottom surface (or lower surface) of the front glass TCG. The light absorption layer LAB can absorb a portion of an external light incident from the outside into the display panel PNL and absorb a portion of the external light that is reflected inside the display panel PNL and output to the outside, so that a reflectance of the display apparatus DIS2 can decrease and a visibility of the display apparatus DIS2 can be improved.

For example, in the present disclosure, by minimizing a reflection of the external light by the color filter layer of the COE structure and the light absorption layer LAB without a polarizing plate, it is possible to improve a visibility.

The light absorption layer LAB can be formed by including dyes or pigments in a liquid resin and coating the bottom of the front glass TCG with the liquid resin, or by including an ultraviolet (UV) absorber and/or a light stabilizer in the liquid resin and coating the bottom of the front glass TCG with the liquid resin. The UV absorber can be 2-methylphenyl 4-methylbenzoate, but is not limited thereto. For example, the UV absorber can be a benzotriazol-based material, a benzophenone-based material, an oxalic acid anilide-based material, or a cyanacrylate-based material.

The light stabilizer can be a Tinuvin-based amine light stabilizer (Hindered Amine Light Stabilizer). The light stabilizer can absorb alkyl radicals and peroxide radicals generated by exposure to ultraviolet rays to stop a chain reaction, so that it blocks ultraviolet rays.

In addition, both the ultraviolet absorber and the light stabilizer can be contained in the light absorption layer LAB.

The light absorption layer LAB can be formed to have a thickness of about 2 μm to 3 μm, but is not limited thereto.

In the display apparatus DIS2 according to the embodiment of the present disclosure, with the COE structure (see FIG. 4) in which the color filter layer 192 is disposed on the encapsulation layer 160, the light absorption layer LAB is formed on the bottom (lower) surface of the front glass TCG which is disposed on the display panel PNL. Accordingly, the reflectance for the external light incident from the outside can be further reduced. According to the embodiment of the present disclosure, since the reflectance for the external light incident from the outside is reduced to about 24% or less, the reflectance can be further reduced compared to about 30% of an external light reflectance when only a COE structure is applied. Accordingly, a visibility of the display apparatus DIS2 can be further improved.

In one example, the light absorption layer LAB can be disposed inside the display panel PNL rather than the front member CW, for example, below or over the encapsulation layer 160 of FIG. 4, or over the color filter layer 192.

However, when the light absorption layer LAB is formed inside the display panel PNL, a thickness of the display panel PNL can increase. Thus, when the foldable display apparatus DIS2 is unfolded and folded, cracks can be generated in some layers such as the light absorption layer LAB and/or the encapsulation layer 160 due to the increase in compressive stress and tensile stress.

On the other hand, in other examples of the present disclosure, the light absorption layer LAB is disposed inside the front member CW. In the present disclosure, since a thickness of the front member CW is increased by the light absorption layer LAB, it can cause compressive stress and tensile stress of the front member CW to increase when folding. However, in the case of the front member CW, two layers of the adhesives ADH_1 and ADH2 are disposed on the bottom surface (lower surfaces) of the front member CW and inside the front member CW, and these adhesives ADH_1 and ADH2 are located relatively low. Thus, the compressive stress and tensile stress which may be caused by the light absorption layer LAB can be absorbed, so that an effect due to a small increase of compressive stress and tensile stress can be minimized.

In other words, when the light absorption layer LAB is formed inside the display panel PNL, a limitation can occur when folding the display panel PNL, whereas when the light absorption layer LAB is formed within the front member CW as in the present disclosure, no such limitation arises when folding of the display panel PNL.

As described above, in the present disclosure, since the color filter layer 192 is disposed on the encapsulation layer 160, a reflection of a light incident from the outside can be minimized without using a separate polarizing plate. Accordingly, while improving a visibility of the organic electroluminescent display apparatus DIS2, a thickness of the organic electroluminescent display apparatus DIS2 can be minimized, and a manufacturing cost thereof can be reduced.

In addition, in the present disclosure, since the light absorption layer LAB is provided to absorb an external light input from the outside, a light reflection can be further reduced, and thus a visibility of the display apparatus DIS2 can be further improved.

Furthermore, in the present disclosure, by forming the light absorption layer LAB inside the front member CW rather than the display panel PNL, an increase in compressive stress and tensile stress due to an increase in thickness can be minimized, so that limitations such cracks which can be caused in the display device PNL when folding can be prevented or minimized.

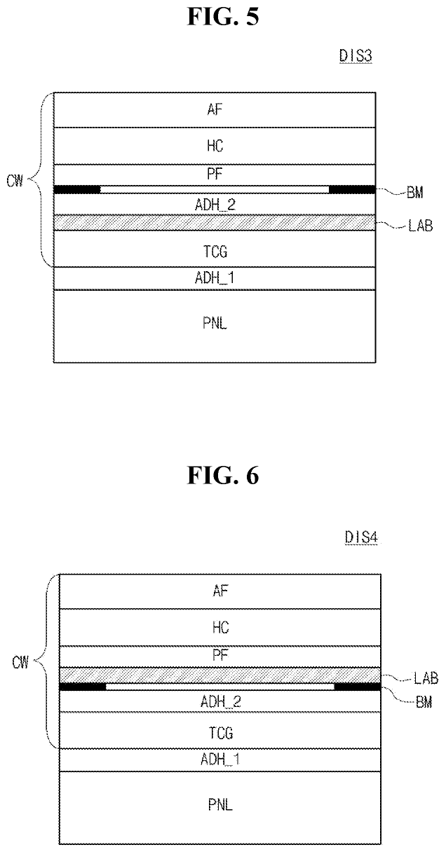

FIG. 5 is a view illustrating a third example of a display apparatus according to an embodiment of the present disclosure. Explanations of the same structure as the example shown in FIG. 3 can be simplified or omitted, and only different structure can be explained in detail.

As shown in FIG. 5, the display apparatus DIS3 according to this example of the present disclosure can include a display panel PNL on which an actual image is displayed, a front member CW which is disposed on the display panel PNL and protects the display panel PNL, and a first adhesive ADH_1 between the front member CW and the display panel PNL.

The front member CW can include a front glass TCG disposed on the display panel PNL, a protective film PF disposed on the front glass TCG, and a coating layer HC and a functional layer AF disposed on the protective film PF. The front glass TCG can be attached to the display panel PNL by the first adhesive ADH_1, and the protective film PF can be attached to the front glass TCG by the second adhesive ADH_2.

In addition, the light absorption layer LAB can be directly coated to a top (or upper) surface of the front glass TCG, and the coating layer HC can be directly laminated on the protective film PF, and the functional layer AF can be directly laminated on the coating layer HC. For instance, the light absorption layer LAB can be disposed directly below the second adhesive ADH_2 and directly above the front glass TCG.

The light absorption layer LAB can be formed by including dyes or pigments in a liquid resin and coating the bottom of the front glass TCG with the liquid resin, or by including an ultraviolet absorber or a light stabilizer in the liquid resin and coating the bottom of the front glass TCG with the liquid resin.

As described above, even in the display apparatus DIS3 according to an embodiment of the present disclosure, the light absorption layer LAB is formed on the top (or upper) surface of the front glass TCG and inside the front member CW. Accordingly, the light absorption layer LAB absorbs a part of an external light incident into the panel PNL and absorbing a part of the external light that is reflected inside of the display panel PNL and output to the outside, and thus a reflectance of the display apparatus DIS3 can be reduced, thereby improving a visibility of the display apparatus DIS3.

The light absorption layer LAB of the embodiment of the present disclosure is formed to have a thickness of about 2 μm to 3 μm, but is not limited thereto.

FIG. 6 is a view illustrating a fourth example of a display apparatus according to an embodiment of the present disclosure. Explanations of the same structure as the example shown in FIG. 3 can be simplified or omitted, and only different structure can be explained in detail.

As shown in FIG. 6, a display apparatus DIS4 according to this example of the present disclosure can include a display panel PNL on which an actual image is displayed, a front member CW which is disposed on the display panel PNL and protects the display panel PNL, and a first adhesive ADH_1 between the front member CW and the display panel PNL.

The front member CW can include a front glass TCG disposed on the display panel PNL, a protective film PF disposed on the front glass TCG, and a coating layer HC and a functional layer AF disposed on the protective film PF. The front glass TCG can be attached to the display panel PNL by the first adhesive ADH_1, and the protective film PF can be attached to the front glass TCG by the second adhesive ADH_2.

In addition, the light absorption layer LAB can be directly coated to a bottom/lower surface of the protective film PF, and a black matrix BM can be formed along an edge of a bottom/lower surface of the light absorption layer LAB. The coating layer HC can be directly laminated on the protective film PF, and the functional layer AF can be directly laminated on the coating layer HC. For instance, the light absorption layer LAB can be directly disposed on the black matrix BM which is directly disposed on the front glass TCG via the second adhesive ADH_2.

The light absorption layer LAB can be formed by including dyes or pigments in a liquid resin and coating the bottom of the front glass TCG with the liquid resin, or by including an ultraviolet absorber or a light stabilizer in the liquid resin and coating the bottom of the front glass TCG with the liquid resin.

Even in the display apparatus DIS4 according to this example of the present disclosure, the light absorption layer LAB is formed on the bottom (or lower) surface of the protective film PF and inside the front member CW. Accordingly, the light absorption layer LAB absorbs a part of an external light incident into the panel PNL and absorbing a part of the external light that is reflected inside of the display panel PNL and output to the outside, and thus a reflectance of the display apparatus DIS4 can be reduced, thereby improving a visibility of the display apparatus DIS4.

The light absorption layer LAB of the embodiment of the present disclosure is formed to have a thickness of about 2 μm to 3 μm , but is not limited thereto.

In the examples of FIGS. 3 to 6, only one layer of the light absorption layer LAB is formed in the front member CW, but two or three layers of the light absorption layers LAB can be formed. For example, the light absorption layer LAB can be formed on the top (upper) surface and the bottom (lower) surface of the front glass TCG, can be formed on the top surface of the front glass TCG and the bottom (lower) surface of the protective film PF, or can be formed the bottom (lower) surface of the front glass TCG and the bottom (lower) surface of the protective film PF. Alternatively, the light absorption layer LAB can be formed on the top and bottom (lower) surfaces of the front glass TCG and the bottom (lower) surface of the protective film PF.

As such, when the plurality of light absorption layers LAB are formed, each of the plurality of light absorption layers LAB can have a thickness of 2 μm or less as a number of the light absorption layers LAB increases. For example, when two light absorption layers LAB are formed inside the front member CW, each light absorption layer LAB can be formed to have a thickness of 0.5 μm to 2 μm, and when three light absorption layers LAB are formed inside the front member CW, each light absorption layer LAB can be formed to have a thickness of 0.3 μm to 1.5 μm.

In addition, when the plurality of light absorption layers LAB are formed inside the front member CW, the light absorption layers LAB can have the same thickness or different thickness.

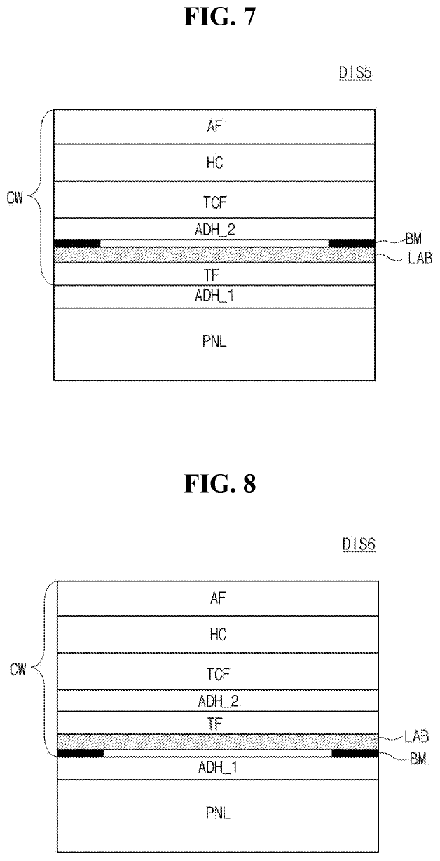

FIG. 7 is a view illustrating a fifth example of a display apparatus according to an embodiment of the present disclosure. Explanations of the same structure as the example shown in FIG. 3 can be simplified or omitted, and only different structure can be explained in detail.

As shown in FIG. 7, a display device DIS5 according to this example of the present disclosure can include a display panel PNL on which an actual image is displayed, a front member which is disposed on the display panel PNL and protects the display panel PNL, and a first adhesive ADH_1 between the front member CW and the display panel PNL.

The front member CW can include a first film TF disposed on the display panel PNL, a second film TCF disposed on the first film TF, and a coated layer HC and a functional layer AF disposed on the second film TCF.

The first film TF can be attached to the display panel PNL by the first adhesive ADH_1, and the second film TCF can be attached to the first film TF by a second adhesive ADH_2. Both the first and second film TF and TCF can protect the display panel PNL from external impact and stress.

The first film TF can be a transparent film such as polyethylene terephthalate, but is not limited thereto. For example, the transparent film TF can be a triacetyl cellulose, a cycloolefin polymer, or a combination thereof.

The second film TCF can be made of color polyimide (CPI), and can transmit an image of the display panel PNL to the outside as it is and protect the display panel PNL from an external impact and an external environment or stress.

The light absorption layer LAB can be directly coated on a top surface (or upper surface) of the first film TF. A black matrix BM can be formed along an edge of the top surface of the light absorption layer LAB to prevent a light output from the display panel PNL from leaking to the edge of the display apparatus DIS. The coating layer HC can be directly laminated on the second film TCF, and the functional layer AF can be directly laminated on the coating layer HC.

The black matrix BM can be formed of a metal oxide such as CrOx, a black resin, or black ink, but is not limited thereto.

The light absorption layer LAB can be formed by including dyes or pigments in a liquid resin and coating the bottom of the front glass TCG with the liquid resin, or by including an ultraviolet absorber or a light stabilizer in the liquid resin and coating the bottom of the front glass TCG with the liquid resin.

Even in the display apparatus DIS5 according to this example of the present disclosure, the light absorption layer LAB is formed on the top surface of the first film TF and inside the front member CW. Accordingly, the light absorption layer LAB absorbs a part of an external light incident into the panel PNL and absorbing a part of the external light that is reflected inside of the display panel PNL and output to the outside, and thus a reflectance of the display apparatus DIS5 can be reduced, thereby improving a visibility of the display apparatus DIS5.

The light absorption layer LAB of the embodiment of the present disclosure is formed to have a thickness of about 2 μm to 3 μm, but is not limited thereto.

FIG. 8 is a view illustrating a sixth example of a display apparatus according to an embodiment of the present disclosure. Explanations of the same structure as the example shown in FIG. 7 can be simplified or omitted, and only different structure can be explained in detail.

As shown in FIG. 8, a display apparatus DIS6 according to this example of the present disclosure can include a display panel PNL on which an actual image is displayed, a front member CW which is disposed on the display panel PNL and protects the display panel PNL, and a first adhesive ADH_1 for attaching the front member CW to the display panel PNL.

The front member CW can include a first film TF disposed on the display panel PNL, a second film TCF disposed on the first film TF, and a coating layer HC and a functional layer AF disposed on the second film TCF.

The first film TF can be attached to the display panel PNL by the first adhesive ADH_1, and the second film TCF can be attached to the first film TF by the second adhesive ADH_2.

A light absorption layer LAB can be directly coated to a bottom/lower surface of the first film TF. A black matrix BM can be formed along an edge of a bottom/lower surface of the light absorption layer LAB. The coating layer HC can be directly laminated on the second film TCF, and the functional layer AF can be directly laminated on the coating layer HC.

As such, even in the display apparatus DIS6 according to this example of the present disclosure, the light absorption layer LAB is formed on the lower surface of the first film TF and inside the front member CW. Accordingly, the light absorption layer LAB absorbs a part of an external light incident into the panel PNL and absorbing a part of the external light that is reflected inside of the display panel PNL and output to the outside, and thus a reflectance of the display apparatus DIS6 can be reduced, thereby improving a visibility of the display apparatus DIS6.

The light absorption layer LAB of the embodiment of the present disclosure is formed to have a thickness of about 2 μm to 3 μm, but is not limited thereto.

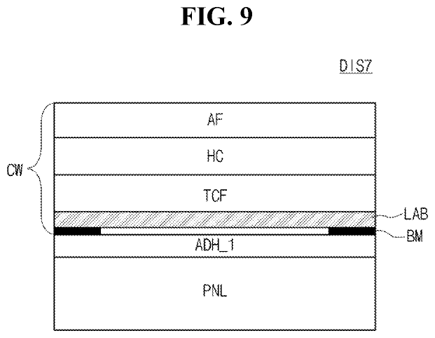

FIG. 9 is a view illustrating a seventh example of a display apparatus according to an embodiment of the present disclosure. Explanations of the same structure as the example shown in FIG. 8 can be simplified or omitted, and only different structure can be explained in detail.

As shown in FIG. 9, a display apparatus DIS7 according to this example of the present disclosure can include a display panel PNL on which an actual image is displayed, a front member CW which is disposed on the display panel PNL and protects the display panel PNL, and a first adhesive ADH_1 attached between the front member CW and the display panel PNL.

The front member CW can include a second film TCF disposed on the display panel PNL, and a coating layer HC and a functional layer AF disposed on the second film TCF.

The second film TCF can be attached to the display panel PNL by the first adhesive ADH_1, and a light absorption layer LAB can be directly coated on a bottom/lower surface of the second film TCF. In addition, a black matrix BM can be formed along an edge of a bottom/lower surface of the light absorption layer LAB. The coating layer HC can be directly laminated on the second film TCF, and the functional layer AF can be directly laminated on the coating layer HC.

Even in the display apparatus DIS7 according to this example of the present disclosure, the light absorption layer LAB is formed on the bottom surface of the second film TCF and inside the front member CW. Accordingly, the light absorption layer LAB absorbs a part of an external light incident into the panel PNL and absorbing a part of the external light that is reflected inside of the display panel PNL and output to the outside, and thus a reflectance of the display apparatus DIS7 can be reduced, thereby improving a visibility of the display apparatus DIS7.

The display apparatus according to the embodiments of the present disclosure can be described as follows.

The display apparatus according to the embodiments of the present disclosure includes a display panel for displaying an image, a front member disposed on the display panel, and a light absorption layer disposed inside the front member.

According to some embodiments of the present disclosure, the light absorption layer can be formed of black resin.

According to some embodiments of the present disclosure, the light absorption layer can be formed of a resin containing a UV absorber and/or a light stabilizer.

According to some embodiments of the present disclosure, a first adhesive can be disposed between the display panel and the front member.

According to some embodiments of the present disclosure, the front member can include a front glass disposed on the display panel, a protective film disposed on the front glass, and a coating layer disposed on the protective film.

According to some embodiments of the present disclosure, the light absorption layer can be disposed on a bottom surface of the front glass.

According to some embodiments of the present disclosure, the light absorption layer can be disposed on a top surface of the front glass.

According to some embodiments of the present disclosure, the light absorption layer can be disposed on a bottom surface of the protective film.

According to some embodiments of the present disclosure, the front member can include a first film disposed on the display panel, a second film disposed on the first film, and a coating layer disposed on the second film.

According to some embodiments of the present disclosure, the light absorption layer can be disposed on a top surface of the first film.

According to some embodiments of the present disclosure, the light absorption layer can be disposed on a bottom surface of the first film.

According to some embodiments of the present disclosure, the front member can include a second film disposed on the display panel, and a coating layer disposed on the second film.

According to some embodiments of the present disclosure, the light absorption layer can be disposed on a bottom surface of the second film.

According to some embodiments of the present disclosure, the display panel can include a substrate, a thin film transistor disposed on the substrate, a light emitting element disposed on the thin film transistor, an encapsulation layer disposed on the light emitting element, and a color filter layer disposed on the encapsulation layer.

According to some embodiments of the present disclosure, the encapsulation layer can include a first encapsulation layer disposed on the light emitting element, a second encapsulation layer disposed on the first encapsulation layer, and a third encapsulation layer disposed on the second encapsulation layer.

According to some embodiments of the present disclosure, the first encapsulation layer and the third encapsulation layer can be formed of an inorganic material.

According to some embodiments of the present disclosure, the second encapsulation layer can be formed of an organic material

According to some embodiments of the present disclosure, the display panel can further include a touch sensor disposed on the encapsulation layer.

As described above, in the present disclosure, the color filter layer can be disposed on the encapsulation layer, and a reflection of a light incident from the outside can be minimized without using a separate polarizing plate. Accordingly, while improving a visibility of the display apparatus, a thickness of the organic electroluminescent display apparatus can be minimized, and a manufacturing cost thereof can be reduced.

In addition, in the present disclosure, since the light absorption layer is provided to absorb an external light input from the outside, a light reflection can be further reduced, and thus a visibility of the display apparatus can be further improved.

Furthermore, in the present disclosure, by forming the light absorption layer inside the front member rather than the display panel, an increase in compressive stress and tensile stress due to an increase in thickness is minimized, so that limitations such cracks which can be caused in the display device PNL when folding, can be prevented.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display apparatus, comprising:
a display panel;
a front member disposed on the display panel; and
a light absorption layer disposed inside the front member.

2. The display apparatus of claim 1, wherein the front member protects the display panel, and the light absorption layer absorbs an external light incident on the display apparatus.

3. The display apparatus of claim 1, wherein the light absorption layer is formed of a black resin, or has a thickness of about 2 μm to 3 μm.

4. The display apparatus of claim 1, wherein the light absorption layer is formed of a resin containing at least one of an ultraviolet (UV) absorber and a light stabilizer.

5. The display apparatus of claim 1, further comprising:
a first adhesive disposed between the display panel and the front member; and
a black matrix disposed inside the front member.

6. The display apparatus of claim 1, wherein the front member further includes:
a front glass disposed on the display panel;
a protective film disposed on the front glass; and
a coating layer disposed on the protective film.

7. The display apparatus of claim 6, wherein the light absorption layer is disposed under a lower surface of the front glass.

8. The display apparatus of claim 6, wherein the light absorption layer is disposed on an upper surface of the front glass.

9. The display apparatus of claim 6, wherein the light absorption layer is disposed under a lower surface of the protective film.

10. The display apparatus of claim 1, wherein the front member further includes:
a first film disposed on the display panel;
a second film disposed on the first film; and
a coating layer disposed on the second film.

11. The display apparatus of claim 10, wherein the light absorption layer is disposed on an upper surface of the first film.

12. The display apparatus of claim 10, wherein the light absorption layer is disposed under a lower surface of the first film.

13. The display apparatus of claim 10, wherein the first film is transparent, and the second film includes a color polyimide.

14. The display apparatus of claim 1, wherein the front member further includes:
a film disposed on the display panel; and
a coating layer disposed on the film,
wherein the light absorption layer is disposed on a lower surface of the film.

15. The display apparatus of claim 1, wherein the display panel includes:
a thin film transistor disposed on a substrate;
a light emitting element disposed on the thin film transistor;
an encapsulation layer disposed on the light emitting element; and
a color filter layer disposed on the encapsulation layer.

16. The display apparatus of claim 15, wherein the encapsulation layer includes:
a first encapsulation layer disposed on the light emitting element;
a second encapsulation layer disposed on the first encapsulation layer; and
a third encapsulation layer disposed on the second encapsulation layer.

17. The display apparatus of claim 16, wherein the first encapsulation layer and the third encapsulation layer are formed of an inorganic material, or
the second encapsulation layer is formed of an organic material.

18. The display apparatus of claim 15, wherein the display panel further includes a touch sensor disposed on the encapsulation layer.

19. A display apparatus, comprising:
a display panel including a plurality of pixels disposed on a substrate; and
a protective module disposed on an upper surface of the display panel,
wherein the protective module includes:
a light absorption layer disposed inside the protective module, and
a black matrix disposed on or below portions of the light absorption layer, and
wherein the display panel includes:
a light emitting element disposed on the substrate,
an encapsulation layer disposed on the light emitting element, and
a color filter layer disposed on the encapsulation layer.

20. The display apparatus of claim 19, wherein the protective module further includes:
a front glass disposed on the display panel;
a protective film disposed on the front glass; and
a coating layer disposed on the protective film.

21. The display apparatus of claim 19, wherein the protective module further includes:
at least one film disposed on the display panel; and
a coating layer disposed on the at least one film.
